(19) United States
(12) Patent Application Publication
(10) Pub. No.: US 2025/0252764 A1
(43) Pub. Date: Aug. 7, 2025

(54) SYSTEMS AND METHODS FOR STRUCTURED MULTI-PHASE REVIEW OF COMPLEX IMAGES

(71) Applicant: Pakked Inc, San Marino, CA (US)

(72) Inventor: Rupen Chanda, Austin, TX (US)

(73) Assignee: Pakked Inc, San Marino, CA (US)

(21) Appl. No.: 18/434,603

(22) Filed: Feb. 6, 2024

(51) Int. Cl. G06V 30/148; G06F 3/04845; G06V 30/12

(52) U.S. Cl. CPC G06V 30/153; G06F 3/04845; G06V 30/127

(57) ABSTRACT

The devices, systems, and methods described herein are directed to obtaining user feedback regarding an image containing text and graphics. In some examples, the image is analyzed to detect one or more portions of the image that contain text, which are sequentially displayed to a user. The user provides feedback regarding the text. Each of the portions of the image that contain graphics are displayed to the user, and the user provides feedback regarding the graphics. In some examples, the text and/or graphics are rotated and/or enlarged before being displayed to the user.

### FIELD

The subject matter described herein relates to systems and methods for obtaining user feedback regarding a complex image and more particularly to guiding a user through a structured, multi-phase review process.

### BACKGROUND

In some applications, information may be presented in a non-traditional format (e.g., in a two-dimensional (2D) or three-dimensional (3D) space). For example, information may be presented as a combination of text, diagram, computer-aided design (CAD) drawings, images, and/or 3D content. In some cases, such non-traditional content needs to be reviewed and approved by one or more parties.

### SUMMARY

The devices, systems, and methods described herein are directed to obtaining user feedback regarding an image containing text and graphics. In some examples, the image is analyzed to detect one or more portions of the image that contain text, which are sequentially displayed to a user. The user provides feedback regarding the text. Each of the portions of the image that contain graphics are displayed to the user, and the user provides feedback regarding the graphics. In some examples, the text and/or graphics are rotated and/or enlarged before being displayed to the user.

### BRIEF DESCRIPTION OF THE DRAWINGS

FIG. 1 is a block diagram of an example of a system for obtaining user feedback regarding an image containing text and graphics in which a local computing device obtains the user feedback regarding the image.

FIG. 2 is a block diagram of an example of a system for obtaining user feedback regarding an image containing text and graphics in which the user interacts with a local computing device and a remote computing device performs at least some of the functionality required to obtain the user feedback regarding the image.

FIG. 3 is a flow chart of an example of a method for obtaining user feedback regarding an image containing text and graphics.

FIG. 4A shows an example of a digital proof that can be sent to obtain user feedback regarding an image containing text and graphics.

FIG. 4B shows an example of the digital proof from FIG. 4A in which each portion of the image is defined by one of a plurality of cells of a grid overlayed on top of the image.

FIG. 4C shows an example of the digital proof from FIG. 4B in which a user is partially finished with their review of the image.

FIG. 4D shows an example of the digital proof from FIG. 4C in which a user has zoomed in to a portion of the image that is currently under review.

FIG. 4E shows an example of the digital proof from FIG. 4B in which a user is nearing completion of their review of the image.

FIG. 4F shows an example of the digital proof from FIG. 4E in which a user has zoomed in to the final portion of the image and is about to complete their review of the image.

### DETAILED DESCRIPTION

In certain industries, it is vital for one or more parties to be able to efficiently and accurately review, comment on, and approve complex images. These complex images may include a combination of computer-aided design (CAD) drawings and artwork. For example, in the packaging and labeling industry, a single mistake can cause many millions of lost dollars, product recalls, and/or lawsuits.

The current process for reviewing and approving two-dimensional (2D) or three-dimensional (3D) content is very unstructured. Today when a review and approval of this type of 2D or 3D content is needed, a review requester will request one or more reviewers to review a particular image or images, which may contain words, sentences, paragraphs, pages, and/or diagrams/images/drawings. In current processes, a reviewer may receive a portable document format (PDF) file with a request that the reviewer review and approve (by signing) the PDF file. One problem with this approach is that these files are often filled with a significant number of detailed drawings, text, logos, etc. that are overlayed on top of a CAD drawing.

One of the problems with the current review of images containing CAD diagrams is that the reviewer needs to review each part of the CAD diagram and must keep a mental account of which parts of the CAD diagram have already been reviewed. This problem is exacerbated by the fact that many CAD diagrams are highly complex and detailed, requiring the reviewer to continuously zoom in/out, pan/scroll, and/or rotate the image to see all of the detailed information that needs to be reviewed. Oftentimes, a reviewer cannot properly review all the details of a CAD diagram (and overlayed artwork) in one session, which creates a greater chance of error if the reviewer is forced to keep a mental account of which parts of the CAD diagram have already been reviewed. In addition, CAD drawings can have a large amount of text that may include detailed measurements. Moreover, some of the included text may not be written horizontally for easy review. Rather, some of the text may be written vertically or with other angular rotation.

Thus, the reviewer must rely on their own mental account of which portions of the CAD drawing have been reviewed to ensure that they have reviewed the entire CAD drawing. Assuming the reviewer approves of the entire CAD drawing, they can then commit their signature/approval. However, conventional review/approval solutions do not provide any structural aid to the reviewer to facilitate their review and enable them to confidently sign/approve the document. Thus, without structured review flow, the reviewer experiences greater difficulties in reviewing the document, has a higher likelihood of committing errors during the review process, and has a lower level of confidence in approving the document.

The devices, systems, and methods described herein are directed to obtaining user feedback regarding an image containing text and graphics. In some examples, the image is analyzed to detect one or more portions of the image that contain text, which are sequentially displayed to a user. The user provides feedback regarding the text. Each of the portions of the image that contain graphics are displayed to the user, and the user provides feedback regarding the graphics. In some examples, the text and/or graphics are rotated and/or enlarged before being displayed to the user.

Although the different examples of devices, systems, and methods for obtaining user feedback may be described herein separately, any of the features of any of the examples may be added to, omitted from, or combined with any other example. Similarly, any of the features of any of the examples may be performed in parallel or performed in a different manner/order than that described or shown herein.

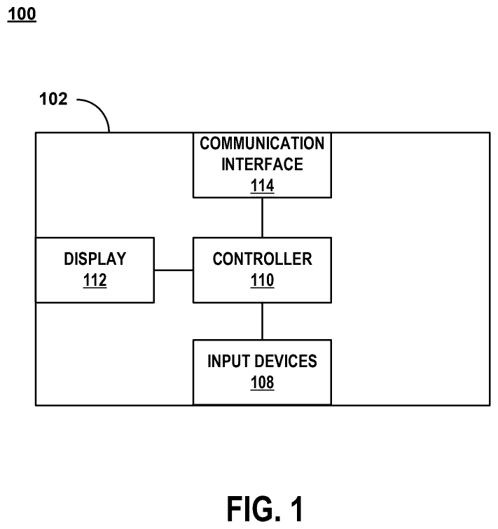

FIG. 1 is a block diagram of an example of a system for obtaining user feedback regarding an image containing text and graphics in which a local computing device obtains the user feedback regarding the image. In the example shown in FIG. 1, system 100 includes local computing device 102. In some examples, local computing device 102 can be any on-site computing device that can receive and process data associated with an image. For example, local computing device 102 could be a tablet computer, a laptop computer, a smartphone, or a desktop computer.

System 100 includes input devices 108, controller 110, display 112, and communication interface 114 of local computing device 102. In the example shown in FIG. 1, input devices 108 include a mouse and a keyboard. However, in other examples, input devices 108 may include one or more of the following: a mouse, a keyboard, a touchscreen, a microphone, and a camera. Of course, any other suitable input devices may be included, in other examples.

Controller 110 includes any combination of hardware, software, and/or firmware for executing the functions described herein. An example of a suitable controller 110 includes software code running on a microprocessor or processor arrangement connected to memory (not explicitly shown in FIG. 1).

Display 112 includes one or more devices suitable for displaying images to a user. In the example shown in FIG. 1, display 112 includes a single screen of local computing device 102. In other examples, display 112 may include multiple screens connected to local computing device 102. Of course, any other suitable display devices may be included, in other examples.

Communication interface 114 may be any suitable wired or wireless interface by which local computing device 102 communicates with other computing devices, either directly or indirectly (e.g., via a network). For example, communication interface 114 may be a wired communication interface (e.g., Universal Serial Bus, RS422, or Ethernet connection), in some examples. In other examples, communication interface 114 may be a wireless communication interface (e.g., Bluetooth, Wi-Fi, cellular, etc.).

As used herein, a user that requests one or more other users to review an image may be referred to as a “review requester,” and a user that reviews the image may be referred to as a “reviewer.” For simplicity, some of the examples described herein involve a single review requester and a single reviewer. However, in other examples, there may be more than one review requester and/or more than one reviewer.

For example, a design firm may create a digital proof (e.g., image) of product packaging for customer approval. The digital proof may include a CAD drawing with artwork, including a logo and text, overlayed on top of the CAD drawing. A single user (e.g., review requester) at the design firm may send the image, along with a request for review, feedback, and approval, to a customer.

In some examples, the customer may have a single user review and provide feedback regarding the image. However, in other examples, the customer may have multiple users (e.g., reviewers) review the image and provide their feedback regarding the image. For example, the customer may have someone from their marketing department review the image for proper logo placement, coloring, sizing, etc. The customer may have someone from their legal department review the image to ensure that the image text reflects proper legal disclaimers. The customer may have someone from their operations team review the image to ensure that the packaging has the correct dimensions and that the packaging material will fold in the proper locations to ensure that the product will be securely contained within the package and that the folds will not interfere with the logos and/or text.

In still further examples, the review requester at the design firm may send the image to be reviewed by multiple parties. For example, the customer may be a company that produces the product that will be placed within the package. An outside law firm may be retained by the customer to review the legal disclaimers that will be printed on the packaging. A packaging company may be responsible for actually manufacturing the packaging. Thus, there may be a reviewer at each of these different entities. The resulting feedback from each reviewer can be obtained and provided separately to the review requester. Alternatively, the review requester can use an online file-sharing platform to share the document containing the image (e.g., digital proof) with one or more reviewers such that any feedback, comments, and/or approvals submitted by any of the reviewers is reflected on the shared file so that other reviewers (and the review requester) can see the feedback and, optionally, respond with their own agreement/disagreement, comment, or response to the feedback provided by other reviewers.

In operation, a review requester utilizes a computing device (not shown in FIG. 1) to send an image, containing text and graphics, to a reviewer with a request to review/approve the image. In some examples, prior to sending the image, the review requester may use or more input devices of their own computing device to submit an indication (e.g., identification) of one or more areas of the image for which feedback is requested from the user (e.g., reviewer). For example, the review requester may indicate one or more specific portions of the image where the reviewer is requested to (1) offer feedback (e.g., comments), (2) answer questions, (3) indicate approval (e.g., via initials or signature), or (4) some combination of these options. In further examples, the review requester may indicate whether the reviewer has editing privileges such that the reviewer can edit the image, possibly with an indication that the image has been edited by the reviewer.

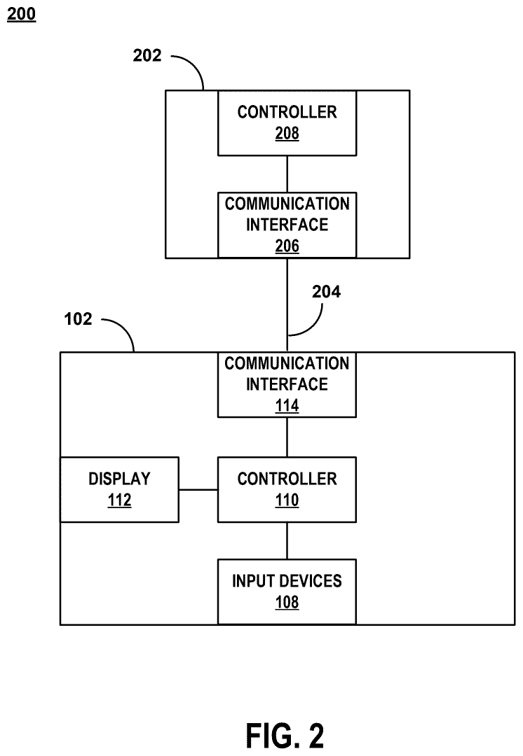

A user (e.g., reviewer) utilizes local computing device 102 to receive an image (e.g., image data) from another computing device (e.g., remote computing device 202 of FIG. 2) via communication interface 114. As mentioned above, the image contains text and graphics. In some examples, the image is a two-dimensional (2D) image. In other examples, the image is a three-dimensional (3D) image. In further examples, the image is a computer-aided design (CAD) drawing. In still further examples, the image is a CAD drawing with artwork overlayed on top of the CAD drawing. For example, the artwork may include a logo, drawing, photograph, and/or text, among others.

Local computing device 102 utilizes controller 110 to analyze the image to detect one or more portions of the image that contain text. In some examples, each portion of the image is defined by one of a plurality of cells of a grid overlayed on top of the image. In other examples, at least one portion of the image is defined by the user (e.g., reviewer) via a marquee area selector. As used herein, a marquee area selector is a marquee tool that enables a user to define the location and size of a portion of the image that they would like to review. In some examples, a user can select a marquee area with the marquee tool by enabling the marquee tool on local computing device 102; moving a cursor (via a mouse) to a desired location on the image (shown on the display); clicking on the desired location, holding the mouse button down while dragging the marquee tool to define a desired location and size of the image, and releasing the mouse button once the desired marquee area has been selected; and confirming that the selected area is a portion of the image that the user wishes to review.

Local computing device 102 utilizes display 112 to sequentially display, to the user (e.g. reviewer), each of the one or more portions of the image that contain text. In some examples in which the text is displayed to the user, controller 110 may rotate at least a portion of the text before the text is displayed to the user. Rotation of the text may facilitate review of the image in instances in which the text is not written horizontally (e.g., when some of the text is written vertically or with another angular rotation). In some examples in which the text is displayed to the user, controller 110 may enlarge at least a portion of the text before the text is displayed to the user. Enlarging the text may facilitate review of the image in instances in which the text is written in a small font size.

Upon review of the portions of the image that contain text, the user (e.g., reviewer) utilizes input devices 108 to submit feedback regarding the text contained in each of the one or more portions of the image that contain text. In some examples, the feedback comprises an indication of approval (e.g., via initials, signature, or entering another input indicating approval). In other examples, the feedback comprises a suggested revision and/or a comment. In further examples, the reviewer may enter revisions, additions, and/or deletions directly to the text, possibly with an indication that the reviewer has changed the text. For example, a text box on a side pane displayed during the review process may enable the user to enter revisions, comments, and/or suggestions, in some examples.

Local computing device 102 utilizes display 112 to display, to the user (e.g. reviewer), one or more portions of the image that contain graphics. In some examples, controller 110 may rotate at least a portion of the graphics before the graphics are displayed to the user. Rotation of the graphics may facilitate review of the image in instances in which the graphics are not positioned horizontally (e.g., when some of the graphics are positioned vertically or with another angular rotation). In some examples, controller 110 may enlarge at least a portion of the graphics before the graphics are displayed to the user. Enlarging the graphics may facilitate review of the image in instances in which the graphics are small in relation to the overall image.

Upon review of the portions of the image that contain graphics, the user (e.g., reviewer) utilizes input devices 108 to submit feedback regarding the graphics contained in each of the one or more portions of the image that contain graphics. In some examples, the feedback comprises an indication of approval (e.g., via initials, signature, or entering another input indicating approval). In other examples, the feedback comprises a suggested revision and/or a comment. In further examples, the reviewer may enter revisions, additions, and/or deletions directly to the graphics, possibly with an indication that the reviewer has changed the graphics.

Although the foregoing example describes that the user first reviews the portions of the image that contain text and then reviews the portions of the image that contain graphics, the user may begin by reviewing the portions of the image that contain graphics and then review the portions of the image that contain text, in other examples. In further examples, the user may simultaneously review the portions of the image that contain text and the portions of the image that contain graphics.

In still further examples, the system can be configured to provide a guided, structured multi-phase review of the image, where the system automatically guides the reviewer through the review process. For example, the reviewer can indicate completion of their review of a particular portion of the image by submitting a particular type of feedback (e.g., initials, signature, etc.). Upon receiving this indication, the system can guide the reviewer to a next portion of the image for review, in some examples. This guided review sequence continues until the reviewer has reviewed all relevant portions of the image.

In this regard, the guided sequence can be customized based on the role of the reviewer, in some examples. For example, a review requester can configure the system to guide a reviewer from a law firm or legal department through a sequence that only includes a review of the text (e.g., for legal disclaimers, etc.). Similarly, a review requester can configure the system to guide a reviewer from a packaging manufacturer through a sequence that only includes a review of the locations of the folds of the packaging. However, a review requester can configure the system to guide a reviewer from a marketing department through a sequence that only includes a review of the text to ensure that the product description/instructions are “on brand” and a review of the graphics to ensure the logo size, placement, and color are correct.

FIG. 2 is a block diagram of an example of a system for obtaining user feedback regarding an image containing text and graphics in which the user interacts with a local computing device and a remote computing device performs at least some of the functionality required to obtain the user feedback regarding the image. The example shown in FIG. 2 is similar to FIG. 1 except that, in system 200, local computing device 102 transmits, via communication interface 114, feedback received from a user (e.g., reviewer) to remote computing device 202 via communication link 204. In the example shown in FIG. 2, communication link 204 is at least partially wired (e.g., through a network). However, communication link 204 may be wireless, in other examples.

In operation, remote computing device 202 utilizes controller 208 to analyze the image to detect one or more portions of the image that contain text, similar to the functionality described above in connection with controller 110 of FIG. 1. In the example of FIG. 2, controller 208 also performs the additional functions described above in connection with controller 110 of FIG. 1, including rotating and/or enlarging portions of the image containing text prior to displaying the text to the user, rotating and/or enlarging portions of the image containing graphics prior to displaying the graphics to the user, etc.

Based on the image analysis performed by remote computing device 202, data is provided to local computing device 102 to sequentially display, to the user (e.g. reviewer), one or more portions of the image that contain text. Based on the image analysis performed by remote computing device 202, data is provided to local computing device 102 to display, to the user, one or more portions of the image that contain graphics. The user of local computing device 102 submits feedback, via input devices 108, regarding the text and graphics of the image. The user feedback is transmitted to remote computing device 202 via communication link 204.

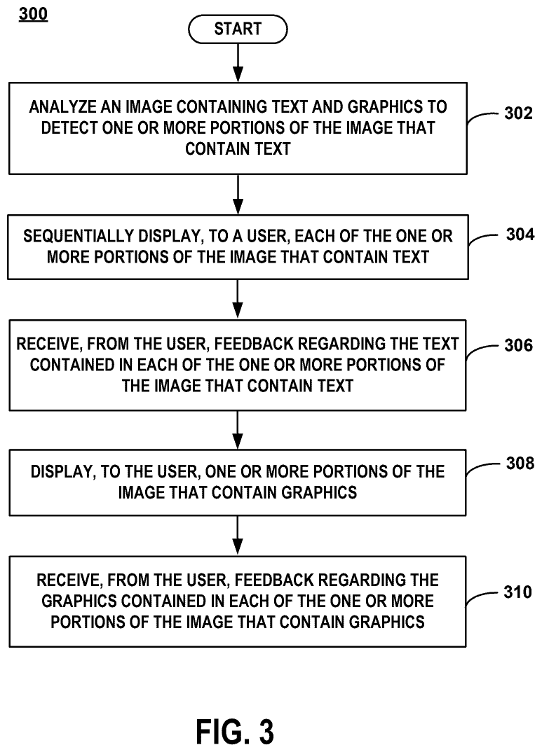

FIG. 3 is a flow chart of an example of a method for obtaining user feedback regarding an image containing text and graphics. The method 300 begins at step 302 with analyzing an image containing text and graphics to detect one or more portions of the image that contain text. At step 304, each of the one or more portions of the image that contain text are sequentially displayed to a user. At step 306, feedback is received, from the user, regarding the text contained in each of the one or more portions of the image that contain text. At step 308, one or more of the portions of the image that contain graphics are displayed to the user. At step 310, feedback is received, from the user, regarding the graphics contained in each of the one or more portions of the image that contain graphics. In other examples, one or more of the steps of method 300 may be omitted, combined, performed in parallel, or performed in a different order than that described herein or shown in FIG. 3. In still further examples, additional steps may be added to method 300 that are not explicitly described in connection with the example shown in FIG. 3.

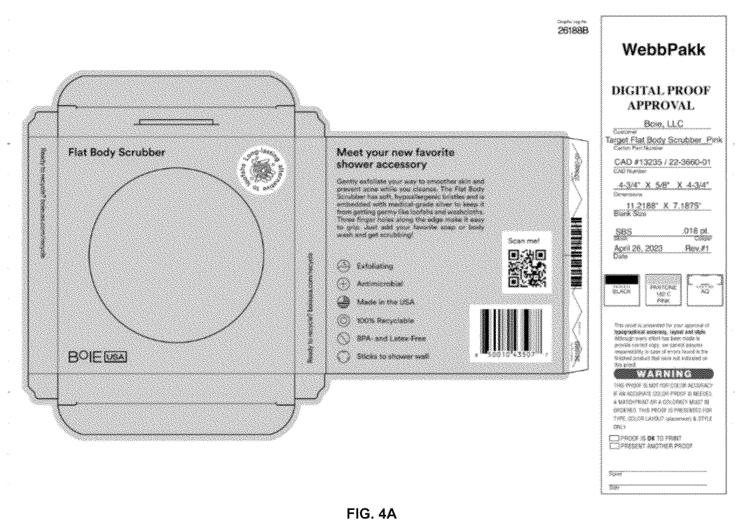

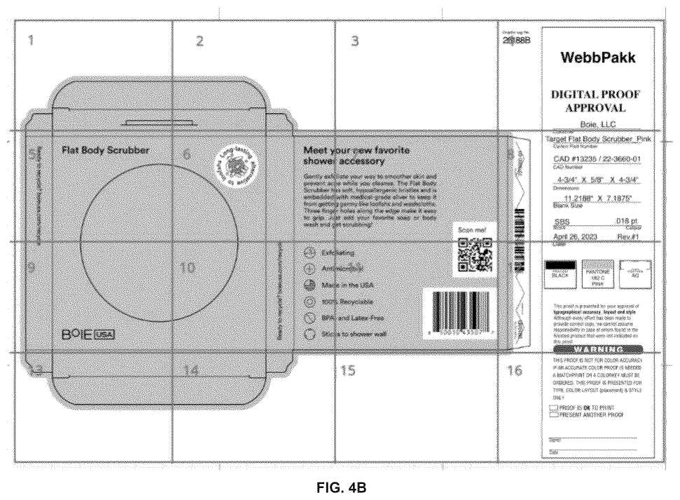

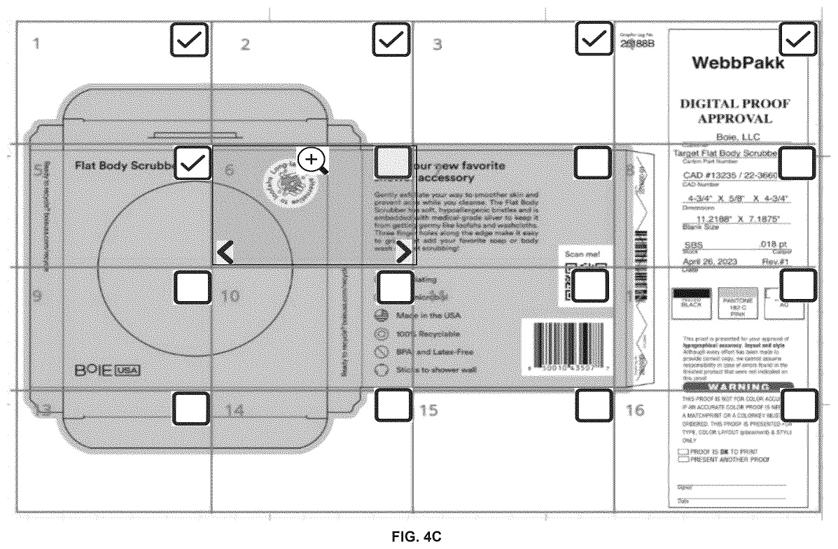

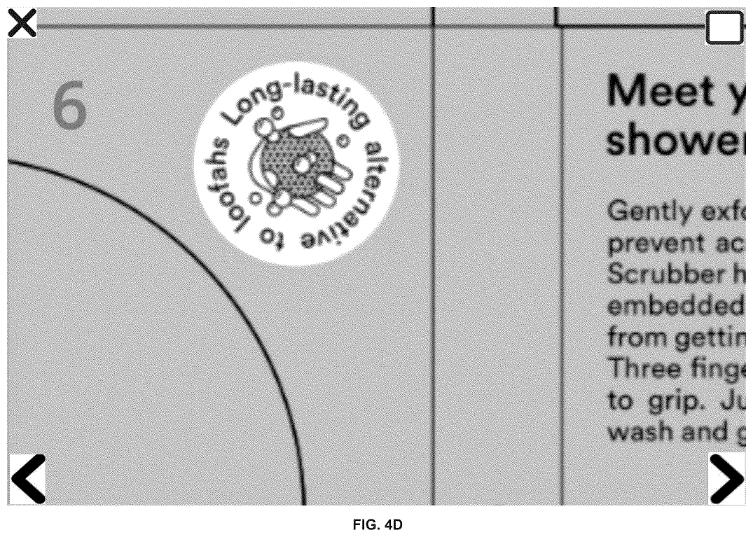

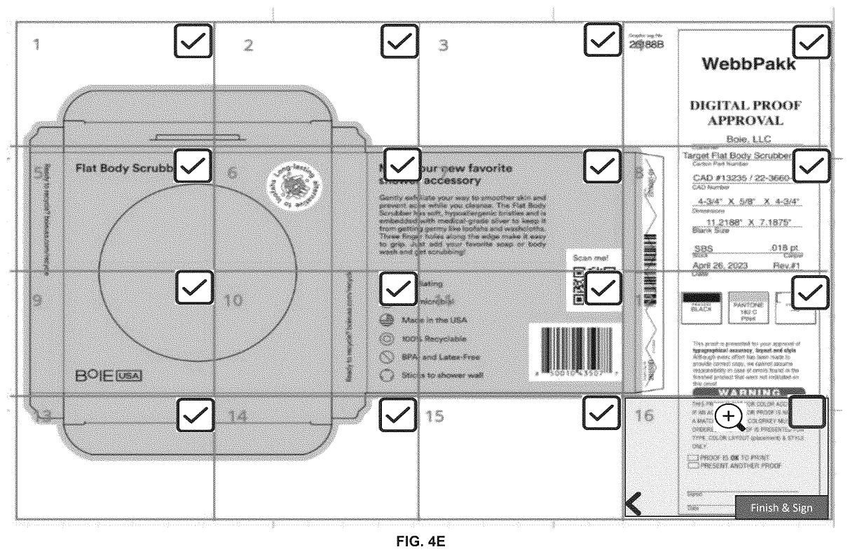

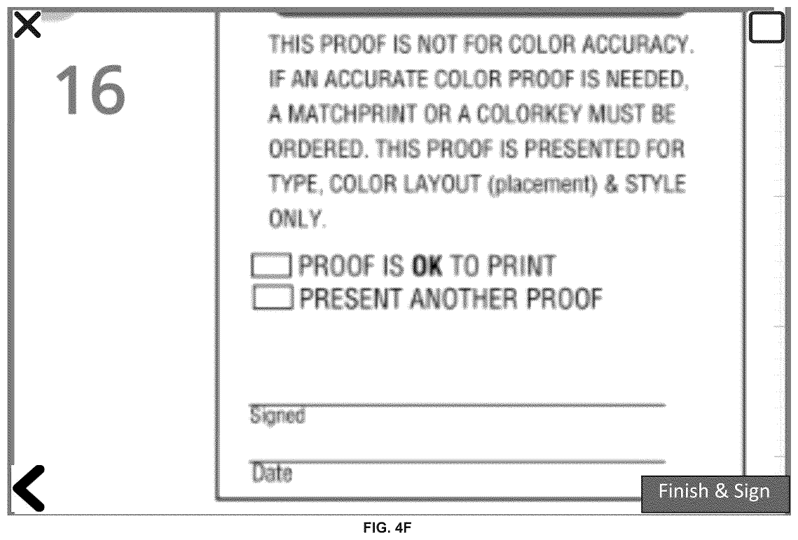

FIG. 4A shows an example of a digital proof that could be sent to obtain user feedback regarding an image containing text and graphics. More specifically, FIG. 4A shows the layout of packaging that is to be used for a flat body scrubber. As can be seen in FIG. 4A, the image contains text and graphics that will be printed on the packaging, as well as the locations of the folds of the packaging.

FIG. 4B shows an example of the digital proof from FIG. 4A in which each portion of the image is defined by one of a plurality of cells of a grid overlayed on top of the image. In the example shown in FIG. 4B, each portion of the image is defined by one of the cells of a 4×4 grid overlaid on top of the image. However, any other suitable number, size, and/or configuration of cells may be utilized, in other examples.

FIG. 4C shows an example of the digital proof from FIG. 4B in which a user is partially finished with their review of the image. More specifically, FIG. 4C shows the stage at which the reviewer has completed their review of the first five portions (e.g., cells) of the image. In the example shown in FIG. 4C, the completion of the review of a particular portion of the image/cell is indicated by a check mark within the cell. However, in other examples, any other suitable indicator (e.g., reviewer's initials/signature, color coding, shading, etc.) may be used to demonstrate that a review of a particular portion of the image has been completed. Moreover, it should be appreciated that, in further examples, the reviewer may not review the portions of the image in any particular order and may elect to review the various portions of the image in any order they choose.

As the reviewer conducts their review of the image, the reviewer may move back to a previous portion/cell by clicking on the previous button (“<”) located within the current portion/cell under review. Likewise, a reviewer may move forward to the next portion/cell by clicking on the next button (“>”) located within the current portion/cell under review. In some examples, clicking the next button (“>”) may also be used to demonstrate that a review of a particular portion of the image has been completed.

If the reviewer would like to review a particular portion of the image in a zoomed in state, they can indicate their desire to zoom in on a particular portion. In the example shown in FIG. 4C, the reviewer clicks on the zoom button (e.g., magnifying glass) located within a particular portion/cell to zoom in on that portion.

FIG. 4D shows an example of the digital proof from FIG. 4C in which a user has zoomed in to a portion of the image that is currently under review. More specifically, FIG. 4D shows that the reviewer is currently reviewing portion number six of the image. If everything in this portion of the image is acceptable, the reviewer may approve this portion of the image by placing a check mark in the upper right corner of the cell or clicking the next button (“>”). However, the reviewer may also add a note to this portion of the image, indicating their feedback (e.g., approval, requested revisions/deletions/additions, etc.) regarding the text and/or graphics located within this portion of the image.

FIG. 4E shows an example of the digital proof from FIG. 4B in which a user is nearing completion of their review of the image. More specifically, FIG. 4E shows the stage at which the reviewer has completed their review of all of the portions (e.g., cells) of the image with the exception of the final portion/cell. FIG. 4F shows an example of the digital proof from FIG. 4E in which a user has zoomed in to the final portion of the image and is about to complete their review of the image. In this final portion/cell, the reviewer may simply place a check mark in the upper right corner of the cell. However, the reviewer may also sign/initial and/or date the image to indicate completion of their review (e.g., by clicking the Finish & Sign button).

Clearly, other examples and modifications of the foregoing will occur readily to those of ordinary skill in the art in view of these teachings. The above description is illustrative and not restrictive. The examples described herein are only to be limited by the following claims, which include all such examples and modifications when viewed in conjunction with the above specification and accompanying drawings. The scope of the foregoing should, therefore, be determined not with reference to the above description alone, but instead should be determined with reference to the appended claims along with their full scope of equivalents.

What is claimed is:

1. A method for obtaining user feedback regarding an image containing text and graphics, the method comprising:
analyzing the image to detect one or more portions of the image that contain text;
sequentially displaying, to a user, each of the one or more portions of the image that contain text;
receiving, from the user, feedback regarding the text contained in each of the one or more portions of the image that contain text;
displaying, to the user, one or more portions of the image that contain graphics; and
receiving, from the user, feedback regarding the graphics contained in each of the one or more portions of the image that contain graphics.

2. The method of claim 1, wherein the image is a two-dimensional (2D) image.

3. The method of claim 1, wherein the image is a three-dimensional (3D) image.

4. The method of claim 1, wherein the image is a computer-aided design (CAD) drawing.

5. The method of claim 4, wherein the image is a CAD drawing with artwork overlayed on top of the CAD drawing.

6. The method of claim 1, further comprising:
rotating at least a portion of the text before displaying the text to the user.

7. The method of claim 1, further comprising:
enlarging at least a portion of the text before displaying the text to the user.

8. The method of claim 1, further comprising:
rotating at least a portion of the graphics before displaying the graphics to the user.

9. The method of claim 1, further comprising:
enlarging at least a portion of the graphics before displaying the graphics to the user.

10. The method of claim 1, wherein each portion of the image is defined by one of a plurality of cells of a grid overlayed on top of the image.

11. The method of claim 1, wherein at least one portion of the image is defined by the user via a marquee area selector.

12. The method of claim 1, wherein feedback comprises an indication of approval.

13. The method of claim 1, wherein feedback comprises a suggested revision.

14. The method of claim 1, further comprising:
receiving, from another user, an indication of one or more areas of the image for which feedback is requested from the user.

15. A system for obtaining user feedback regarding an image containing text and graphics, the system comprising:
a controller to analyze the image to detect one or more portions of the image that contain text;
a display to sequentially display, to a user, each of the one or more portions of the image that contain text; and
one or more input devices to receive, from the user, feedback regarding the text contained in each of the one or more portions of the image that contain text,
the display further displays, to the user, one or more portions of the image that contain graphics,
the one or more input devices further receive, from the user, feedback regarding the graphics contained in each of the one or more portions of the image that contain graphics.

16. The system of claim 15, wherein the image is a two-dimensional (2D) image.

17. The system of claim 15, wherein the image is a three-dimensional (3D) image.

18. The system of claim 15, wherein the image is a computer-aided design (CAD) drawing.

19. The system of claim 18, wherein the image is a CAD drawing with artwork overlayed on top of the CAD drawing.

20. The system of claim 15, wherein the controller rotates at least a portion of the text before the text is displayed to the user.

21. The system of claim 15, wherein the controller enlarges at least a portion of the text before the text is displayed to the user.

22. The system of claim 15, wherein the controller rotates at least a portion of the graphics before the graphics are displayed to the user.

23. The system of claim 15, wherein the controller enlarges at least a portion of the graphics before the graphics are displayed to the user.

24. The system of claim 15, wherein each portion of the image is defined by one of a plurality of cells of a grid overlayed on top of the image.

25. The system of claim 15, wherein at least one portion of the image is defined by the user via a marquee area selector.

26. The system of claim 15, wherein feedback comprises an indication of approval.

27. The system of claim 15, wherein feedback comprises a suggested revision.

28. The system of claim 15, further comprising:
one or more other input devices to receive, from another user, an indication of one or more areas of the image for which feedback is requested from the user.
